(19) United States
(12) Patent Application Publication
(10) Pub. No.: US 2005/0224807 A1
(43) Pub. Date: Oct. 13, 2005

(54) Low dielectric constant carbon films

(76) Inventors: Kramadhati V. Ravi, Atherton, CA (US); Michael C. Garner, Pleasanton, CA (US)

Correspondence Address: TROP PRUNER & HU, PC, 8554 KATY FREEWAY, SUITE 100, HOUSTON, TX, 77024, US

(21) Appl. No.: 10/809,243

(22) Filed: Mar. 25, 2004

(51) Int. Cl. H01L 29/15

(52) U.S. Cl. 257/77

(57) ABSTRACT

Diamond and non-diamond composite film may be exposed to oxygen plasma to gasify the non-diamond forms of carbon, leaving porosity in the resulting structure. In some cases, highly desirable dielectric materials may be formed with high dielectric constants and good mechanical strength.

### BACKGROUND

This invention relates generally to the formation of low dielectric constant carbon films for semiconductor integrated circuit fabrication.

As device dimensions have shrunk and the speed of logic in microprocessor products has increased, a limit is being faced because of the RC time constant associated with interconnects and their related dielectrics. There is now a need to develop new interlayer dielectric materials with decreasing dielectric constants below that of traditional silicon dioxide dielectric material (about 4).

Currently, common interlayer dielectric materials have a low mechanical strength as a result of using doped oxides. One example is carbon doped oxide. Alternatively, common dielectrics may be made of organic materials such as spin-on dielectric. The poor mechanical strength of these existing dielectric materials leads to mechanical and structural problems during wafer processing and assembly operations.

Consequently, there is a need for alternative low dielectric constant materials which exhibit good mechanical strength.

### BRIEF DESCRIPTION OF THE DRAWINGS

FIG. 1 is an enlarged, partial cross-sectional view through one embodiment of the present invention at an early stage of manufacture;

FIG. 2 is an enlarged, partial cross-sectional view of one embodiment of the present invention at a subsequent stage of manufacture;

FIG. 3 is an enlarged, partial cross-sectional view at a subsequent stage of manufacture in accordance with one embodiment of the present invention;

FIG. 4 is an enlarged, partial cross-sectional view at a subsequent stage of manufacture in accordance with one embodiment of the present invention; and

FIG. 5 is an enlarged, cross-sectional view at still a subsequent stage of manufacture in accordance with one embodiment of the present invention.

### DETAILED DESCRIPTION

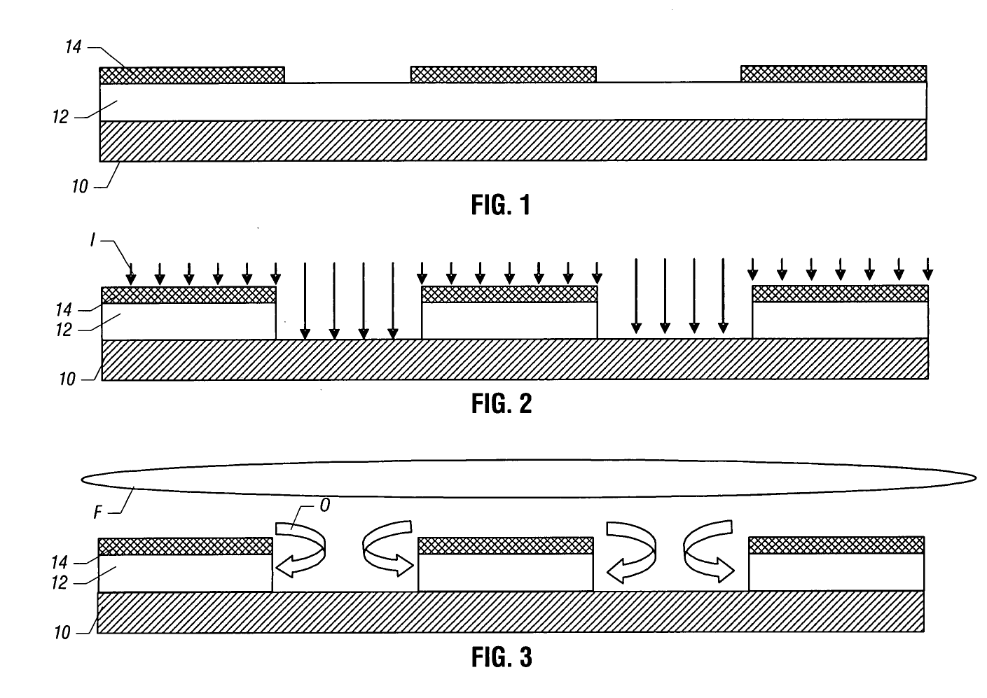

Referring to FIG. 1, a semiconductor substrate 10 may be covered with a diamond-like carbon film 12. The diamond-like carbon film 12 may be formed of a mixture of significant as opposed to trace amounts of both diamond and non-diamond forms of carbon. One example of a non-diamond form of carbon may be graphite.

In one embodiment, the diamond form of carbon may be characterized by a particular type of bonding between carbon atoms. The diamond bonds are Sp3 hybridized, which means the bonds are very strong, which gives diamond its unique properties (very high hardness, modulus, thermal conductivity, etc.).

The diamond material in the film 12 may be deposited using plasma enhanced chemical vapor deposition (CVD) processes using mixtures of a hydrocarbon such as methane and a super saturation of hydrogen. If the ratio of methane to hydrogen is small, e.g., 1 to 3 percent methane and 97 to 99 percent hydrogen, the diamond material may be predominantly composed of Sp3 bonded carbon, i.e., pure diamond films. As the methane concentration, relative to hydrogen is increased, the films become mixed phase films with both diamond bonded (Sp3) carbon and non-diamond bonded (Sp2) carbon, which is often graphite.

The non-diamond form of carbon in the film 12 is made up of carbon whose inter atomic bonds are not Sp3 bonds. Typically, the non-carbon material may be graphite Sp2, amorphous carbon, defects, and the like.

The ratio of diamond-to-non-diamond materials in the film 12 can vary quite widely depending upon the process conditions. For the case of low dielectric constant, high mechanical strength films, in one embodiment 10 to 20 percent methane in hydrogen may be used. The synthesis (deposition) process is such that a high methane to hydrogen ratio is used and a mix of diamond and non-diamond forms of carbon, mixed randomly in the film 12, is the result.

The film 12 may be prepared using plasma enhanced CVD processes using a mixture of a hydrocarbon, such as methane and hydrogen, as the process gas mix. Several CVD techniques can be used to deposit the films including microwave assisted CVD, filament assisted CVD, and direct current (DC) glow discharges. Typically, the methane and hydrogen are cracked by the plasma processes and the byproducts of the cracking process (atomic hydrogen, methyl, and other radicals) appropriately react on the surface of the wafer to result in the formation of diamond material. As described above, the phase purity (Sp3 to Sp2 ratio) of the films can be modulated by changes in the methane to hydrogen ratio.

The diamond-like carbon film 12 may be covered with a photolithographically processed hard mask 14 which has openings positioned at desired points along the hard mask 14. The structure covered by the patterned hard mask 14 is then exposed to an oxygen plasma indicated by the letter I. A reactive ion etching with an oxygen source may be undertaken with substrate bias to increase vertical etching and to reduce lateral etching and undercutting.

As shown in FIG. 3, the etched film structure may be exposed to oxygen plasma indicated at F. In one embodiment, the oxygen plasma may be without substrate bias to etch the sides of the diamond-like carbon film 12 exposed by the reactive ion etching shown in FIG. 2. The exposure to the oxygen plasma creates porosity within the film 12. In one embodiment, the oxygen plasma exposure may be at a pressure of 1 to 20 Torr, at a temperature of 300 to 400 C, and a power of about 1 kilowatt.

In one embodiment, the gasification proceeds from the side of the layer 12. The side attack may reduce dimensional changes to the film 12, compared to etching from all directions. However, the hard mask 14 may also be removed before gasification in some embodiments.

The process conditions may selectively etch and gasify the non-diamond forms of carbon in the film 12 with minimal attack of the diamond bonded material in one embodiment. The resulting porosity in the patterned carbon film 12 reduces the dielectric constant of the film 12. In one embodiment, the dielectric constant may be below 2 with a porosity of about 50 percent.

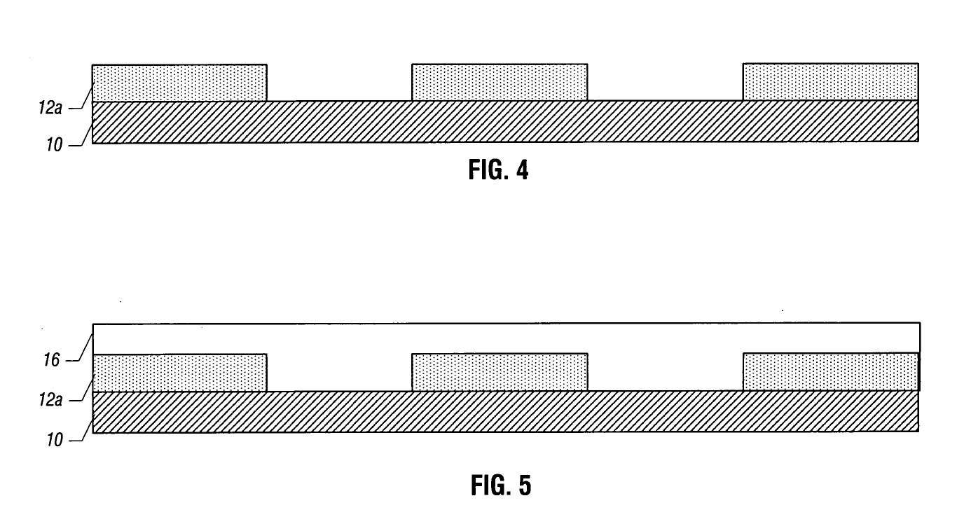

The hard mask 14 may be removed as shown in FIG. 4. Then, as shown in FIG. 5, the copper layer 16 may be plated over the resulting structure to form a damascene structure. The copper layer 16 forms the next level metal layer in a damascene structure. In some embodiments, a barrier layer may be provided between the copper layer 16 and the modified diamond-like carbon film 12a.

Some embodiments of the present invention may exhibit relatively high mechanical strength because of the presence of diamond in the carbon film material. In addition, because of the porosity, the dielectric constant may be reduced because of the presence of micro voids and other internal discontinuities in the film. Thus, the dielectric patterning process may provide desirable dielectric capacitance which has a relatively large effect with closely spaced lines. In some embodiments, greater circuits speeds may result.

In one embodiment, the mixed phased diamond films may be synthesized using a process of deposition, etching by atomic hydrogen, and deposition. In some embodiments, the modulus of the resulting film may be greater than 250 GPa.

While the present invention has been described with respect to a limited number of embodiments, those skilled in the art will appreciate numerous modifications and variations therefrom. It is intended that the appended claims cover all such modifications and variations as fall within the true spirit and scope of this present invention.

1. A method comprising:
forming a film including diamond and non-diamond forms of carbon; and
gasifying carbon to increase the porosity of the film.

2. The method of claim 1 including forming a film of Sp2 and Sp3 carbon.

3. The method of claim 1 including using chemical vapor deposition to deposit said film.

4. The method of claim 1 including forming a film with a mixture of hydrocarbon and a super saturation of hydrogen.

5. The method of claim 4 including adjusting the ratio of hydrocarbon to hydrogen to form a film with both Sp2 and Sp3 bonded carbon.

6. The method of claim 5 including using 10 to 20 percent methane in hydrogen to form Sp2 and Sp3 bonded carbon.

7. The method of claim 1 wherein gasifying carbon includes exposing the film to oxygen plasma.

8. The method of claim 7 including exposing said film to a plasma without bias.

9. The method of claim 8 including exposing said film to plasma attack from the sides of the film while covering the top of the film.

10. The method of claim 1 including forming said film having a dielectric constant less than 2.

11. The method of claim 1 including forming said film having a porosity of about 50 percent.

12. A method comprising:
forming a semiconductor film comprising significant amounts of both Sp3 and Sp2 bonded carbon.

13. The method of claim 12 including gasifying the Sp2 carbon to increase the porosity of the film.

14. The method of claim 12 including gasifying said Sp2 film by exposing said film to oxygen plasma.

15. The method of claim 14 including exposing said film to oxygen plasma while the top of said film is covered and the sides of said film are exposed.

16. The method of claim 12 including forming said film with a dielectric constant less than 2.

17. The method of claim 12 including forming said film having a porosity of about 50 percent.

18. A semiconductor structure comprising:
a substrate; and
a film on said substrate, said film including diamond and having a dielectric constant less than 2.

19. The structure of claim 18 wherein said film has a porosity of about 50 percent.

20. The structure of claim 18 including a metallic layer over said film.

21. The structure of claim 20 wherein said metallic layer includes copper.

22. A semiconductor structure comprising:
a substrate; and
a film containing significant amounts of Sp2 and Sp3 bonded carbon.

23-28. (canceled)
